(19) United States
(12) Patent Application Publication
(10) Pub. No.: US 2026/0107803 A1
(43) Pub. Date: Apr. 16, 2026

(54) SEMICONDUCTOR PACKAGE

(71) Applicant: Samsung Electronics Co., Ltd., Suwon-si (KR)

(72) Inventor: Hongjin KIM, Suwon-si (KR)

(21) Appl. No.: 19/223,175

(22) Filed: May 30, 2025

(30) Foreign Application Priority Data
Oct. 11, 2024 (KR) 10-2024-0138537

(51) Int. Cl. H01L 23/538; H01L 23/00; H01L 23/31; H01L 25/04

(52) U.S. Cl. CPC H10W 70/65; H10W 70/611; H10W 74/137; H10W 90/00; H10W 72/01908; H10W 72/9445; H10W 90/24

(57) ABSTRACT

A semiconductor package includes a package substrate including a plurality of bonding pads, a plurality of semiconductor chips mounted on an upper surface of the package substrate, and each including a plurality of pads, the plurality of pads including a power voltage pad, a ground voltage pad, and a first signal pad and a second signal pad adjacent to each other, a plurality of connection lines including a first signal line connecting the first signal pads to the first bonding pad, and a second signal line connecting the second signal pads to the second bonding pad, and a first dummy line disposed between the first signal line and the second signal line.

### CROSS-REFERENCE TO RELATED APPLICATION(S)

This application claims the benefit under 35 USC 119(a) of Korean Patent Application No. 10-2024-0138537 filed on Oct. 11, 2024 in the Korean Intellectual Property Office, the entire disclosure of which is incorporated herein by reference for all purposes.

### BACKGROUND

The present inventive concept relates to a semiconductor package.

A semiconductor package contains one or more semiconductor chips (having integrated circuits formed therein) having a form suitable for use in electronic products. Typically, in a semiconductor package, semiconductor chips may be mounted on a package substrate (e.g., a printed circuit board) and electrically connected to each other using bonding wires, bumps, or inkjet printing. With the development of the electronics industry, various studies are being conducted to improve the reliability of and to miniaturize semiconductor packages. In detail, semiconductor packages that handle high-speed signals should not only be miniaturized but should also provide excellent signal quality.

### SUMMARY

Example embodiments provide a semiconductor package in which a quality of a signal is improved by reducing crosstalk occurring between adjacently disposed signal lines.

According to example embodiments, a semiconductor package includes a package substrate including a plurality of bonding pads, the plurality of bonding pads including a first bonding pad and a second bonding pad; a plurality of semiconductor chips mounted on an upper surface of the package substrate, each of the plurality of semiconductor chips including a respective plurality of pads, wherein for each of the plurality of semiconductor chips, the respective plurality of pads includes a power voltage pad, a ground voltage pad, a first signal pad, and a second signal pad adjacent to the first signal pad; a plurality of connection lines including a first signal line connecting each of the first signal pads to the first bonding pad, a second signal line connecting each of the second signal pads to the second bonding pad, a first connection line connecting each of the power voltage pads to a respective bonding pad of the plurality of bonding pads, and a second connection line connecting each of the ground voltage pads to a respective bonding pad of the plurality of bonding pads; and a first dummy line disposed between the first signal line and the second signal line.

According to example embodiments, a semiconductor package includes a package substrate including a plurality of bonding pads; a plurality of semiconductor chips mounted on an upper surface of the package substrate, each of the plurality of semiconductor chips including a first signal pad and a second signal pad; a plurality of connection lines including a first signal line connecting the first signal pad of each of the plurality of semiconductor chips to a first bonding pad of the plurality of bonding pads, and a second signal line connecting the second signal pad of each of the plurality of semiconductor chips to a second bonding pad of the plurality of bonding pads, wherein from a top down view, each of the plurality of connection lines extends in a first direction parallel to the upper surface of the package substrate, and wherein the first signal pad and the second signal pad are disposed adjacent to each other in a second direction parallel to the upper surface of the package substrate; and a first line extending in the first direction positioned between the first signal line and the second signal line, wherein from a top down view, the first line does not directly connect to and does not extend over any chip pads of the plurality of semiconductor chips.

According to example embodiments, a semiconductor package includes a package substrate including a plurality of bonding pads; a plurality of semiconductor chips mounted on an upper surface of the package substrate, each of the plurality of semiconductor chips including a respective plurality of pads, wherein for each of the plurality of semiconductor chips, the respective plurality of pads includes a pair of pads adjacent to each other that are configured to transmit or receive a data signal; a plurality of connection lines connecting the plurality of pads of each of the plurality of semiconductor chips to respective bonding pads of the plurality of bonding pads, the plurality of connection lines including a first connection line configured to provide a ground voltage, a second connection line configured to provide the ground voltage, and a first signal line and a second signal line respectively connected to the pair of pads of each of the plurality of semiconductor chips; a first dummy line between the pair of pads of each of the plurality of semiconductor chips; a plurality of second dummy lines connecting the first connection line and the second connection line to the first dummy line; and a first insulating pattern disposed between the first signal line, the second signal line, and the plurality of second dummy lines.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a block diagram simply illustrating a semiconductor device according to an example embodiment;

FIG. 2 is a perspective view simply illustrating a semiconductor package according to an example embodiment;

FIG. 3 is a plan view simply illustrating a semiconductor package according to an example embodiment;

FIG. 4 is a cross-sectional view illustrating a cross-section in direction I-I′ of FIG. 2;

FIG. 5 is a cross-sectional view illustrating a cross-section in direction II-II′ of FIG. 2; and

FIGS. 6 to 12 are plan views simply illustrating a semiconductor package according to an example embodiment.

### DETAILED DESCRIPTION

Hereinafter, example embodiments will be described with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

An item, layer, or portion of an item or layer described as “extending” or as extending “lengthwise” in a particular direction has a length in the particular direction and a width perpendicular to that direction, where the length is greater than the width. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

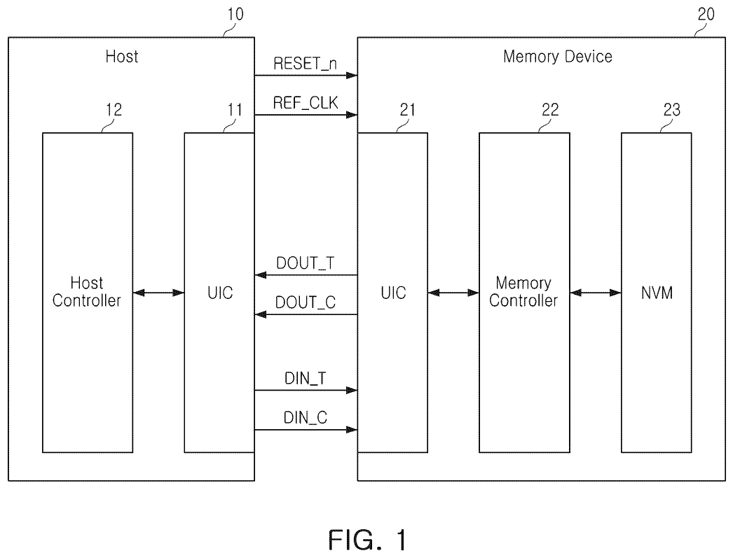

FIG. 1 is a block diagram simply illustrating a semiconductor device according to an example embodiment.

A semiconductor device according to an example embodiment is a device that follows the Universal Flash Storage (UFS) standard announced by Joint Electron Device Engineering Council (JEDEC), and may include a host 10 and a memory device 20.

The host 10 may include a host controller 12, an application, a host driver, a host memory, and a UFS interconnect (UIC) layer (an interface) 11. The host 10 may control the overall operation of the semiconductor device, in detail, operations of other components forming the semiconductor device.

The memory device 20 may function as a nonvolatile storage device that stores data regardless of whether power is supplied, and may have a relatively large storage capacity. The memory device 20 may include a UIC layer 21, a memory controller 22, a nonvolatile memory 23, and the like. Input signals and output signals may be transmitted and received through the UIC layer 11 of the host 10 and the UIC layer 21 of the memory device 20. Referring to FIG. 1, the memory controller 22 and the UIC layer 21 are illustrated separately, but this is not limited thereto, and the UIC layer 21 may be included as a part of the memory controller 22.

The memory device 20 may include a memory controller 22 and a nonvolatile memory 23 that stores data under the control of the memory controller 22. The nonvolatile memory 23 may be composed of a plurality of memory units, and these memory units may include 2D NAND or Vertical NAND (V-NAND) flash memory having a 3D structure, but may also include other types of nonvolatile memory such as PRAM and/or RRAM.

The memory device 20 may be provided as a semiconductor package that is physically separate from the host 10, or may be implemented in the same package as the host 10. In addition, the memory device 20 may be implemented as a solid state device (SSD) or a memory card. This memory device 20 may be a device to which a standard specification such as UFS, embedded multi-media card (eMMC), or non-volatile memory express (NVMe) is applied, but is not necessarily limited thereto.

Between the host 10 and the memory device 20, a line for transmitting a reference clock REF_CLK, a line for transmitting a hardware reset signal RESET_n for the memory device 20, a pair of lines for transmitting a differential input signal pair DIN_T and DIN_C, and a pair of lines for transmitting a differential output signal pair DOUT_T and DOUT_C may be included. Referring to FIG. 1, a pair of lines transmitting a differential input signal pair DIN_T and DIN_C may constitute a receive lane, and a pair of lines transmitting a differential output signal pair DOUT_T and DOUT_C may constitute a transmit lane, respectively.

The receive lane and the transmit lane may transmit data in a serial communication manner, and full-duplex communication between the host 10 and the memory device 20 is possible due to the structure in which the receive lane and the transmit lane are separated. That is, the memory device 20 may transmit data to the host 10 through the transmit lane while receiving data from the host 10 through the receive lane.

The memory device 20 may receive VCC, VCCQ, VCCQ2, and the like, as power supply voltages. VCC is the main power supply voltage for the memory device 20 and may have a value of 2.4 to 3.6 V. VCCQ is a power supply voltage for supplying a low range of voltage, mainly for the memory controller 22, and may have a value of 1.14 to 1.26 V. VCCQ2 is a power supply voltage for supplying a voltage lower than VCC but higher than VCCQ, such as for an input/output interface such as MIPI M-PHY, and may have a value of 1.7 to 1.95 V.

In an example embodiment, high-speed signals may be transmitted between the host 10 and the memory device 20. For example, in the case of UFS4.0 and UFS5.0 currently in mass production, the speed of a signal transmitted from a semiconductor device should be 3 Gbps or higher. As high-speed signals are handled, even small errors may cause signal quality degradation. In particular, when wires transmitting signals are adjacent to each other, mutual inductance and/or capacitance are formed between the wires, which may cause crosstalk that degrades signal quality.

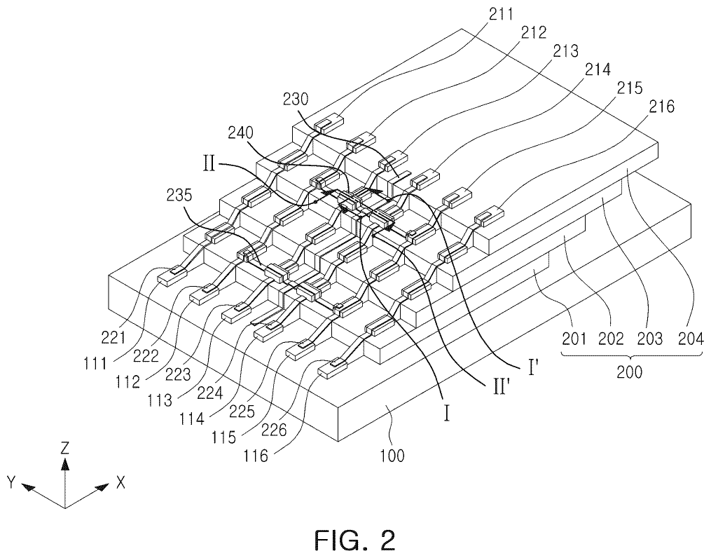

FIG. 2 is a perspective view simply illustrating a semiconductor package according to an example embodiment.

In an example embodiment, the semiconductor package may include a package substrate 100, a plurality of semiconductor chips 200, and a plurality of connection lines 221 to 226. The plurality of semiconductor chips 200 may be mounted on the upper surface of the package substrate 100.

The package substrate 100 may use various types of substrates such as a printed circuit board (PCB), a flexible substrate, and a tape substrate. As an example, the package substrate 100 may be a printed circuit board (PCB) having internal wiring formed therein. The package substrate 100 may include a plurality of bonding pads 111 to 116 disposed on the upper surface thereof and connection pads disposed on the lower surface thereof. The plurality of bonding pads 111 to 116 may be electrically connected to the connection pads through internal wirings. Connection terminals such as solder balls or solder bumps may be attached to the connection pads.

The plurality of semiconductor chips 200 may be stacked on the upper surface of the package substrate 100. Each of the plurality of semiconductor chips 200 may include a plurality of pads 211 to 216 (chip pads that are electrical terminals of the semiconductor chip 200). The plurality of pads 211 to 216 may include a power voltage pad connected to an external device (e.g., host 10) to receive a power voltage, a ground voltage pad connected to an external device to receive a ground voltage, and a signal pad connected to an external device to communicate a signal. The power voltage pads and ground voltage pads may be connected to internal voltage sources of the chips 200 (circuits that regulate voltages and provide internal voltages to the integrated circuits of the semiconductor chips 200). The signal pads may connect to the interface of the memory device (e.g., UIC layer 21) to provide data, address and/or command singals or information to the integrated circuits of the semiconductor chips 200 (e.g., to data I/O buffers, address decoders, and command logic of the semiconductor chips 200). In an example embodiment, the plurality of pads 211 to 216 may be respectively formed at the upper surfaces of the plurality of semiconductor chips 200 near the edge of the upper surfaces of the plurality of semiconductor chips 200. In addition, in the first direction (Z-axis direction) perpendicular to the upper surface of the package substrate, the plurality of semiconductor chips 200 may be stacked in a stepwise manner (e.g., to form a staircase shape), so that the upper surface edges of the plurality of semiconductor chips 200 may all be exposed. Accordingly, the plurality of pads 211 to 216 may be exposed upwardly.

The plurality of connection lines 221 to 226 may electrically connect the plurality of bonding pads 111 to 116 to the plurality of pads 211 to 216, respectively. In an example embodiment, the plurality of connection lines 221 to 226 may be formed by an inkjet printing method. The inkjet printing method may include a step of printing a conductive ink on the package substrate 100 in a predetermined pattern, and may print the pattern on the package substrate 100 without a separate patterning operation.

When at least two signal lines included in the plurality of connection lines 221 to 226 are disposed adjacently, crosstalk that degrades the quality of the signal may occur due to mutual inductance and/or capacitance formed between the at least two signal lines. In particular, in the case of a semiconductor device transmitting a high-speed signal, an error may occur in the operation of the semiconductor device due to crosstalk.

In an example embodiment, at least one dummy line 230 (e.g., a first dummy line) may be disposed between two adjacent signal lines 223 and 224. The dummy line 230 may be in a floating state or may be connected to a power supply voltage or a ground voltage. By disposing at least one dummy line 230 between two adjacent signal lines 223 and 224, the influence of mutual inductance and/or capacitance may be reduced, and crosstalk, degrading the quality of the signal, may be reduced. A semiconductor device having at least one dummy line 230 disposed between two adjacent signal lines 223 and 224 may reduce crosstalk and improve signal quality.

Referring to FIG. 2, the package substrate 100 may include first to sixth bonding pads 111 to 116. The plurality of semiconductor chips 200 may include first to fourth semiconductor chips 201 to 204, and each semiconductor chip may include six pads 211 to 216. However, the number of pads included on each semiconductor chip is not limited thereto and may be more or less than six. The six pads 211 to 216 may include a first pad 211, a second pad 212, a third pad 215, a fourth pad 216, a first signal pad 213, and a second signal pad 214. The first to fourth pads 211, 212, 215 and 216 may each be a power voltage pad or a ground voltage pad.

The first signal pad 213 and the second signal pad 214 may be adjacent to each other. In the third direction (Y-axis direction) parallel to the upper surface of the package substrate 100, the first signal pad 213 and the second signal pad 214 may be disposed closest to each other. For example, there may be no other pads positioned between the first signal pad 213 and the second signal pad 214. The first signal pad 213 and the second signal pad 214 may be a pair of pads that transmit or receive a data signal, which is a differential signal. It should be understood that multiple pairs of adjacent signal pads (as described herein) may be provided with the semiconductor chips 200 (and be connected and function as described herein with respect to the first signal pad 213 and the second signal pag 214).

The plurality of connection lines 221 to 226 may include the first connection line 221, the second connection line 222, the third connection line 225, the fourth connection line 226, the first signal line 223, and the second signal line 224. The first connection line 221 may connect the first pads 211 of each of the semiconductor chips 201 to 204 to each other and to the first bonding pad 111, the second connection line 222 may connect the second pads 212 of each of the semiconductor chips 201 to 204 to each other and to the second bonding pad 112, the third connection line 225 may connect the third pads 215 of each of the semiconductor chips 201 to 204 to each other and to the fifth bonding pad 115, and the fourth connection line 226 may connect the fourth pads 216 of each of the semiconductor chips 201 to 204 to each other and to the sixth bonding pad 116. The first signal line 223 may connect the first signal pads 213 of each of the semiconductor chips 201 to 204 to each other and to the third bonding pad 113, and the second signal line 224 may connect the second signal pads 214 of each of the semiconductor chips 201 to 204 to each other and to the fourth bonding pad 114.

Since the first signal pad 213 and the second signal pad 214 are adjacent to each other, the first signal line 223 and the second signal line 224 may also be adjacent to each other. At least one dummy line 230 may be disposed between the first signal line 223 and the second signal line 224. In an example embodiment, one dummy line 230 may be disposed between the first signal line 223 and the second signal line 224.

In an example embodiment, at least one dummy connection line 235 (e.g., a second dummy line) may electrically connect the dummy line 230 to another connection line that is connected to a power supply voltage or a ground voltage. For example, at least one dummy connection line 235 may connect the dummy line 230 to a second connection line 222 and a third connection line 225. Referring to FIG. 2, two dummy connection lines 235 may connect the dummy line 230 to the second connection line 222, and the other two dummy connection lines 235 may connect the dummy line 230 to the third connection line 225. However, the number of dummy connection lines 235 is not limited thereto and may be more or less than two. The second connection line 222 and the third connection line 225 may be connected to a power supply voltage or to a ground voltage. In the third direction (Y-axis direction) parallel to the upper surface of the package substrate 100, the dummy line 230 may have a width substantially equal to that of each of the plurality of connection lines 221 to 226.

Referring to FIG. 2, the dummy connection line 235 may have an area overlapping (e.g., above) the first signal line 223 and the second signal line 224. The insulating pattern 240 may electrically insulate the dummy connection line 235 from the first signal line 223 and the second signal line 224. In the first direction (Z-axis direction) perpendicular to the upper surface of the package substrate 100, at least one insulating pattern 240 may be disposed between the dummy connection line 235 and the first signal line 223. In the first direction, at least one insulating pattern 240 may be disposed between the dummy connection line 235 and the second signal line 224.

The plurality of connection lines 221 to 226, the dummy line 230, the dummy connection line 235, and the insulating pattern 240 may each be formed by an inkjet printing method and may include a conductive ink. In the first direction (Z-axis direction), the plurality of connection lines 221 to 226 may be formed, the insulating pattern 240 may be formed thereon, and the dummy line 230 and the dummy connection line 235 may be formed thereon.

By disposing at least one dummy line 230 between the first signal line 223 and the second signal line 224 that are disposed adjacent to each other, the mutual inductance and/or capacitance formed between the two signal lines 223 and 224 may be reduced, and the crosstalk that deteriorates the quality of the signal that occurs due to this may also be reduced. Therefore, a semiconductor package in which at least one dummy line 230 is disposed between adjacent signal lines 223 and 224 may improve the quality of a signal.

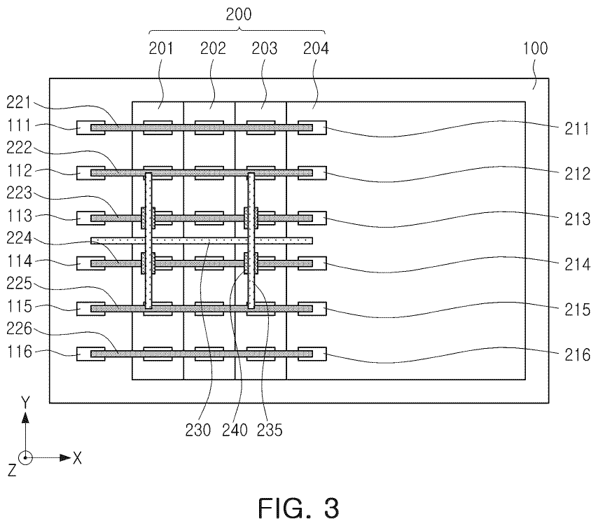

FIG. 3 is a plan view simply illustrating a semiconductor package according to an example embodiment.

Referring to FIGS. 2 and 3 together, FIG. 3 may be a plan view of the semiconductor package according to an example embodiment of FIG. 2 as viewed in the first direction (Z-axis direction). A plurality of semiconductor chips 200 may be mounted on the upper surface of a package substrate 100. The package substrate 100 may include a plurality of bonding pads 111 to 116. Each of the plurality of semiconductor chips 200 may include a plurality of pads 211 to 216.

The plurality of semiconductor chips 200 may be the same semiconductor chips (for example, they may be the same type of semiconductor chip). Therefore, the plurality of pads 211 to 216 included in each of the plurality of semiconductor chips 200 may be arranged in the same order.

The plurality of pads 211 to 216 and the plurality of bonding pads 111 to 116 may be respectively connected through the plurality of connection lines 221 to 226. The plurality of connection lines 221 to 226 may be formed to extend in a second direction (X-axis direction) parallel to the upper surface of the package substrate 100.

The plurality of pads 211 to 216 may include a first signal pad 213 and a second signal pad 214. The first signal pad 213 and the second signal pad 214 may be disposed adjacent to each other. The first signal line 223 may connect the first signal pads 213 of each of the semiconductor chips 200 to each other and to the third bonding pad 113, and the second signal line 224 may connect the second signal pads 214 of each of the semiconductor chips 200 to each other and to the fourth bonding pad 114.

In an example embodiment, a dummy line 230 may be disposed between the first signal line 223 and the second signal line 224. At least one dummy connection line 235 may connect the dummy line 230 to the second connection line 222 and the third connection line 225 connected to the power voltage or the ground voltage. Referring to FIG. 3, two dummy connection lines 235 may connect the dummy line 230 to the second connection line 222, and the other two dummy connection lines 235 may connect the dummy line 230 to the third connection line 225. However, the number of dummy connection lines 235 is not limited thereto, and may be more or less than two.

The insulating pattern 240 may be formed in an area where the dummy connection line 235 and the first signal line 223 and the second signal line 224 overlap. In the second direction (X-axis direction), the width of the insulating pattern 240 may be larger than the width of the dummy connection line 235 and smaller than the width of each of the plurality of pads 211 to 216. The insulating pattern 240 may surround the side and upper surfaces of the first signal line 223. The insulating pattern 240 may surround the side and upper surfaces of the second signal line 224. In an example embodiment, the insulating pattern 240 may surround the side and upper surfaces of a portion of the first signal line 223.

Referring to FIG. 3, the dummy connection line 235 may have an area overlapping with (e.g., above) the first signal pad and the second signal pad of the first semiconductor chip 201, and the first signal pad and the second signal pad of the third semiconductor chip 203. Therefore, in the first direction (Z-axis direction), the insulating pattern 240 may be placed on the first signal pad and the second signal pad of the first semiconductor chip 201, and the first signal pad and the second signal pad of the third semiconductor chip 203. However, the positions of the dummy connection line 235 and the insulating pattern 240 are not limited thereto. The dummy connection line 235 and the insulating pattern 240 may be placed in a portion where the plurality of semiconductor chips 200 are exposed.

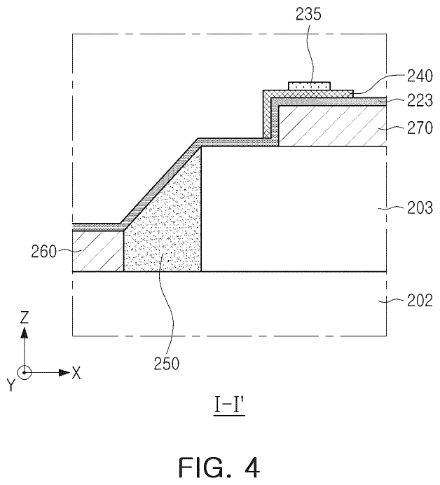

FIG. 4 is a cross-sectional view showing a cross-section in the I-I′ direction of FIG. 2.

Referring to FIG. 2 and FIG. 4 together, FIG. 4 may be a cross-sectional view showing a part of the first signal line 223 of FIG. 2. In an example embodiment, in the first direction (Z-axis direction) perpendicular to the upper surface of the package substrate, the plurality of semiconductor chips may have a structure in which they are stacked in a stepwise manner on the upper surface of the package substrate. The plurality of semiconductor chips may be stacked in the order of a first semiconductor chip 201, a second semiconductor chip 202, a third semiconductor chip 203, and a fourth semiconductor chip 204.

The package substrate may include a plurality of bonding pads. The plurality of semiconductor chips may include a plurality of pads. The plurality of connection lines may connect the plurality of pads to the plurality of bonding pads, respectively. For example, the plurality of semiconductor chips may each include a first signal pad 260, 270, and the first signal line 223 may connect one of the plurality of bonding pads to the first signal pads 260 and 270. For example, as shown in FIG. 4, the third semiconductor chip 203 may have a first signal pad 270 at its upper surface and the second semiconductor chip 202 may have a first signal pad 260 at its upper surface, and the first signal line 223 may connect the first signal pad 270 to the first signal pad 260.

In an example embodiment, an insulator 250 may be disposed between the plurality of semiconductor chips. The insulator 250 may electrically insulate between the plurality of semiconductor chips. Even if the plurality of connection lines are formed along the stacked structure of the plurality of semiconductor chips, the plurality of semiconductor chips may be electrically separated from the plurality of connection lines by disposing the insulator 250.

Referring to FIG. 4, a third semiconductor chip 203 may be stacked on an upper surface of a second semiconductor chip 202. The second semiconductor chip 202 and the third semiconductor chip 203 may include first signal pads 260 and 270, respectively. The first signal line 223 may connect the first signal pads 260 and 270 included in the plurality of semiconductor chips to each other and to one of the plurality of bonding pads. The first signal line 223 may have an area overlapping with (e.g., above) the first signal pads 260 and 270 included in the plurality of semiconductor chips 202 and 203, respectively.

In the first direction (Z-axis direction), the insulating pattern 240 may be disposed on the first signal pad 270 included in the third semiconductor chip 203, and the dummy connection line 235 may be disposed on the insulating pattern 240. In the second direction (X-axis direction), the width of the insulating pattern 240 may be larger than the width of the dummy connection line 235. In an example embodiment, the thicknesses of the plurality of connection lines, the insulating pattern 240, the dummy line, and the dummy connection line 235 in the first direction (Z-axis direction) may be substantially the same, but may be different from each other depending on the method of spraying the conductive ink, or the like.

Referring to FIG. 4, the first signal pad 270, the first signal line 223, the dummy connection line 235, and the insulating pattern 240 included in the third semiconductor chip 203 may have an overlapping area when viewed in the first direction (Z-axis direction). However, the present inventive concept is not limited thereto, and the dummy connection line 235 and the insulating pattern 240 may have an area overlapping with the insulator 250 and may have an area overlapping with the first signal pad included in another semiconductor chip.

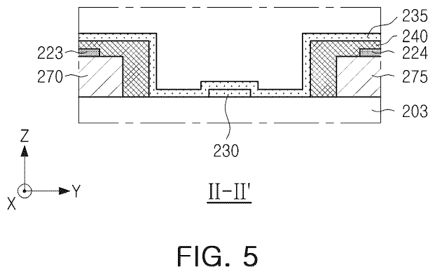

FIG. 5 is a cross-sectional view showing a cross-section in the II-II′ direction of FIG. 2.

Referring to FIG. 5, the third semiconductor chip 203 may include a first signal pad 270 and a second signal pad 275 adjacent to each other. The first signal pad 270 and the second signal pad 275 may be disposed closest to each other in the third direction (Y-axis direction) parallel to the upper surface of the package substrate. For example, there may be no other pad positioned between the first signal pad 270 and the second signal pad 275. In an example embodiment, the first signal pad 270 and the second signal pad 275 may be a pair of pads that transmit or receive a data signal, which is a differential signal.

A package substrate according to an example embodiment may include a first signal line 223 and a second signal line 224. The first signal line 223 may connect the first signal pads 270 of each of the semiconductor chips 200 to each other and to one of the plurality of bonding pads, and the second signal line 224 may connect the second signal pads 275 of each of the semiconductor chips 200 to each other and to another of the plurality of bonding pads.

In an example embodiment, at least one line (e.g., conductive line) may be disposed between the first signal line 223 and the second signal line 224. For example, the at least one line may be at least one dummy line 230. The dummy line 230 may reduce mutual inductance and/or capacitance formed between the first signal line 223 and the second signal line 224, thereby reducing crosstalk generated thereby.

The dummy line 230 may be in a floating state or may be connected to a power supply voltage or a ground voltage. At least one dummy connection line 235 may connect the dummy line 230 to the wires (or pads) connected to the power voltage or the ground voltage. The dummy connection line 235 may have an area overlapping with (e.g., above) the first signal line 223 and/or the second signal line 224. The dummy connection lines described herein may not be necessary to properly convey signals and power (e.g., between the semiconductor chips 200 and/or external devices) through these dummy connection lines (although they may assist proper conveyance of signals through other signal lines). For example, in devices having dummy connection lines connected to wires that are connected to power or ground voltages, if such dummy connection lines were removed, then the power or ground voltages would still be supplied appropriately to the semiconductor chips 200.

Referring to FIG. 5, the insulating pattern 240 may be disposed between the dummy connection line 235 and the first signal line 223 in the first direction (Z-axis direction). The insulating pattern 240 may also be disposed between the dummy connection line 235 and the second signal line 224 in the first direction. The insulating pattern 240 may electrically insulate the dummy connection line 235 from the first signal line 223 and the second signal line 224.

In an example embodiment, the insulating pattern 240 may surround the side and upper surfaces of the first signal line 223 and the first signal pad 270. The insulating pattern 240 may surround the side and upper surfaces of the second signal line 224 and the second signal pad 275.

In the first direction (Z-axis direction), the thickness of a portion of the insulating pattern 240 may be greater than the thickness of the first signal line 223 and the second signal line 224. In the first direction, the thickness of the insulating pattern 240 may be greater than the thickness of at least one dummy connection line 235.

In the third direction (Y-axis direction), the width of the insulating pattern 240 may be greater than the width of each of the plurality of pads. In the third direction (Y-axis direction), the width of the insulating pattern 240 may be greater than the width of each of the plurality of connection lines. The insulating pattern 240 may be in contact with a portion of the upper surface of the third semiconductor chip 203.

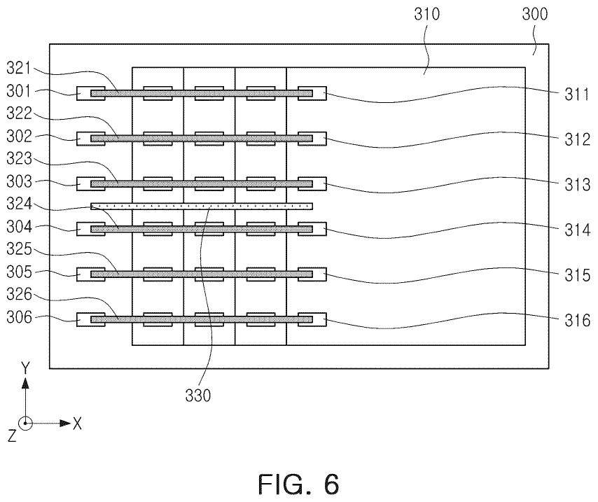

FIGS. 6 to 12 are plan views simply illustrating a semiconductor package according to an example embodiment.

Referring to FIG. 6, a plurality of semiconductor chips 310 may be mounted on the upper surface of a package substrate 300. The package substrate 300 may include a plurality of bonding pads 301 to 306. The plurality of semiconductor chips 310 may each include a plurality of pads 311 to 316. The plurality of bonding pads 301 to 306 and the plurality of pads 311 to 316 may be electrically connected through a plurality of connection lines 321 to 326.

In an example embodiment, the plurality of bonding pads 301 to 306 may include a first bonding pad 303 and a second bonding pad 304. The plurality of pads 311 to 316 may include a first signal pad 313 and a second signal pad 314 that are disposed adjacent to each other. The plurality of connection lines 321 to 326 may include a first signal line 323 and a second signal line 324. The first signal line 323 may connect the first signal pads 313 of each of the semiconductor chips 310 to each other and to the first bonding pad 303, and the second signal line 324 may connect the second signal pads 314 of each of the semiconductor chips 310 to each other and to the second bonding pad 304.

Since the first signal line 323 and the second signal line 324 are disposed adjacent to each other, crosstalk may be formed by mutual inductance and/or capacitance formed between the first signal line 323 and the second signal line 324. In the case of signal lines that transmit high-speed signals, the signal quality may be degraded due to crosstalk.

Referring to FIG. 6, at least one dummy line 330 may be placed between the first signal line 323 and the second signal line 324. At least one dummy line 330 may be in a floating state that is not connected to the power supply voltage or the ground voltage. The dummy line 330 may not connect to any chip pads and may not electrically connect to any external devices. The length of the dummy line 330 (in the X direction) may correspond to the lengths of the connection lines 221 to 226. For example, the dummy line 330 may extend end to end from a row of bonding pads of the package substrate 100 (here, from the row of bonding pads 111 to 116) to a row of chip pads of a semiconductor chip 200 (here, the row of pads 211 to 216 of the uppermost semiconductor chip 204). In addition, no chip pads may exist under the dummy line 330. By placing at least one dummy line 330, the size of the mutual inductance and/or capacitance formed between the first signal line 323 and the second signal line 324 may be reduced, and the crosstalk that occurs due to this may also be reduced. Accordingly, a semiconductor package with improved signal quality may be provided.

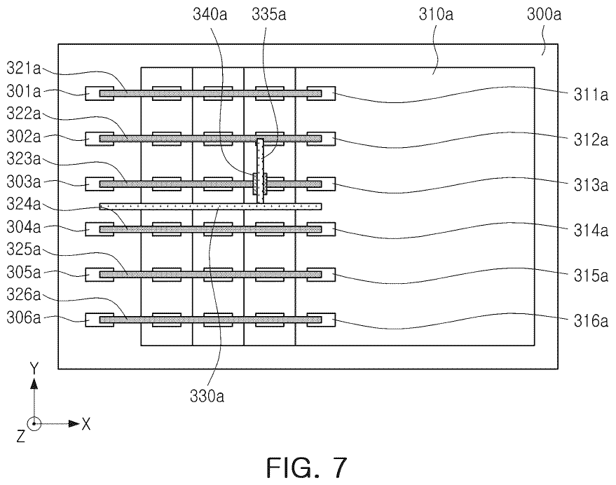

Referring to FIG. 7, a plurality of semiconductor chips 310a may be mounted on the upper surface of the package substrate 300a. The package substrate 300a may include a plurality of bonding pads 301a to 306a. The plurality of semiconductor chips 310a may each include a plurality of pads 311a to 316a. The plurality of bonding pads 301a to 306a and the plurality of pads 311a to 316a may be electrically connected through a plurality of connection lines 321a to 326a.

The first signal line 323a may connect the first signal pads 313a of each of the semiconductor chips 310a to each other and to the third bonding pad 303a, and the second signal line 324a may connect the second signal pads 314a of each of the semiconductor chips 310a to each other and to the fourth bonding pad 304a. Since the first signal line 323a and the second signal line 324a are disposed adjacent to each other, crosstalk may be formed by mutual inductance and/or capacitance formed between the first signal line 323a and the second signal line 324a. In the case of signal lines transmitting a high-speed signal, the signal quality may be degraded due to crosstalk.

Referring to FIG. 7, at least one dummy line 330a may be placed between the first signal line 323a and the second signal line 324a. At least one dummy line 330a may be connected to the first connection line 322a providing the power voltage or ground voltage through at least one dummy connection line 335a. The dummy line 330a may not directly connect to any chip pads and may not electrically connect to any chip pads except those electrically connected via the at least one dummy connection line 335a. The length of the dummy line 330a may correspond to the lengths of the connection lines 221 to 226. For example, the dummy line 330a may extend end to end from a row of bonding pads of the package substrate 100 (here, from the row of bonding pads 111 to 116) to a row of chip pads of a semiconductor chip 200 (here, the row of pads 211 to 216 of the uppermost semiconductor chip 204). In addition, no chip pads may exist under the dummy line 330a. The ends of the dummy line 330a may be electrical stubs. The dummy lines connected to a ground voltage or to a power voltage described elsewhere herein may also have these features of dummy line 330a.

In an example embodiment, the ground voltage pad 312a may be placed adjacent to the first signal pad 313a. The first connection line 322a may electrically connect the second bonding pad 302a, which is one of the plurality of bonding pads 301a to 306a, to the ground voltage pads 312a of each of the semiconductor chips 310a. The first connection line 322a may be placed adjacent to the first signal line 323a. The first connection line 322a is connected to the ground voltage pad 312a, so that the ground voltage may be provided to at least one dummy line 330a.

In the first direction (Z-axis direction), the insulating pattern 340a may be disposed between the first signal line 323a and at least one dummy connection line 335a. The insulating pattern 340a may surround the side and upper surfaces of the first signal line 323a. In the second direction (X-axis direction), the width of the insulating pattern 340a may be larger than the width of the dummy connection line 335a and smaller than the width of each of the plurality of pads 311a to 316a.

By disposing at least one dummy line 330a connected to a power supply voltage or a ground voltage, the size of mutual inductance and/or capacitance formed between two adjacent signal lines 323a and 324a may be reduced, and thus crosstalk formed may also be reduced. Accordingly, a semiconductor package with improved signal quality may be provided.

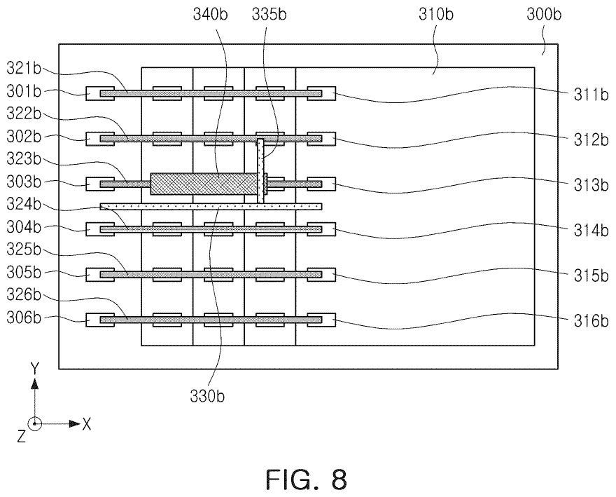

Referring to FIG. 8, at least one dummy line 330b may be disposed between the first signal line 323b and the second signal line 324b that are adjacent to each other. The dummy line 330b may be connected to a power voltage or a ground voltage through at least one dummy connection line 335b.

In an example embodiment, the dummy connection line 335b may have an area overlapping with (e.g., above) at least one signal line. In the first direction (Z-axis direction), the insulating pattern 340b may be disposed between the dummy connection line 335b and at least one signal line. The insulating pattern 340b may surround the side and upper surfaces of the signal line.

Referring to FIG. 8, the insulating pattern 340b may be disposed between the first signal line 323b and the dummy connection line 335b in the first direction (Z-axis direction). In the second direction (X-axis direction), the width of the insulating pattern 340b may be greater than the width of the dummy connection line 335b and each of the plurality of pads 311b to 316b. In an example embodiment, the width of the insulating pattern 340b in the second direction (X-axis direction) may be greater than the combined widths of three pads. In the first direction (Z-axis direction), at least one dummy connection line 335b may be disposed above the insulating pattern 340b. Since the width of the insulating pattern 340b is relatively large, a plurality of dummy connection lines 335b may be disposed above the insulating pattern 340b in the first direction.

By disposing at least one dummy line 330b connected to the power supply voltage or the ground voltage, the size of the mutual inductance and/or capacitance formed between the two adjacent signal lines 323b and 324b may be reduced, and thus the crosstalk formed may also be reduced. Accordingly, a semiconductor package with improved signal quality may be provided.

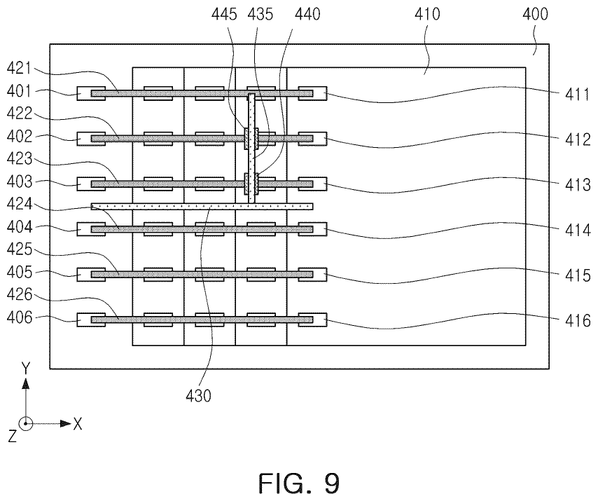

Referring to FIG. 9, at least one dummy line 430 may be disposed between the first signal line 423 and the second signal line 424. The at least one dummy line 430 may be connected to a power voltage or a ground voltage through at least one dummy connection line 435.

In an example embodiment, at least one dummy connection line 435 may connect the first connection line 421 included in the plurality of connection lines 421-426 to at least one dummy line 430. The first connection line 421 may connect the first bonding pad 401 the first pads 411 on each semiconductor chip 410. The first pad 411 may be a power voltage pad or a ground voltage pad. In an example embodiment, the first pad 411 may be a ground voltage pad.

At least one connection line may be disposed between the first connection line 421 and the first signal line 423. Referring to FIG. 9, a second connection line 422 may be disposed between the first connection line 421 and the first signal line 423. The dummy connection line 435 may have an area overlapping (e.g., above) the first signal line 423 and the second connection line 422.

In the first direction (Z-axis direction), the first insulating pattern 440 may be disposed between the first signal line 423 and the dummy connection line 435. In the first direction (Z-axis direction), the second insulating pattern 445 may be disposed between the second connection line 422 and the dummy connection line 435. The first insulating pattern 440 and the second insulating pattern 445 may be physically separated from each other.

In the second direction (X-axis direction), the widths of the first insulating pattern 440 and the second insulating pattern 445 may be larger than the width of the dummy connection line 435 and smaller than the width of each of the plurality of pads 411 to 416. In the third direction (Y-axis direction), the widths of the first insulating pattern 440 and the second insulating pattern 445 may be larger than the width of each of the plurality of pads 411 to 416. The first insulating pattern 440 may electrically separate the first signal line 423 from the dummy connection line 435. The second insulating pattern 445 may electrically separate the second connection line 422 from the dummy connection line 435.

By disposing at least one dummy line 430 connected to a power supply voltage or ground voltage, the size of the mutual inductance and/or capacitance formed between two adjacent signal lines 423 and 424 may be reduced, and thus the crosstalk formed may also be reduced. Accordingly, a semiconductor package with improved signal quality may be provided.

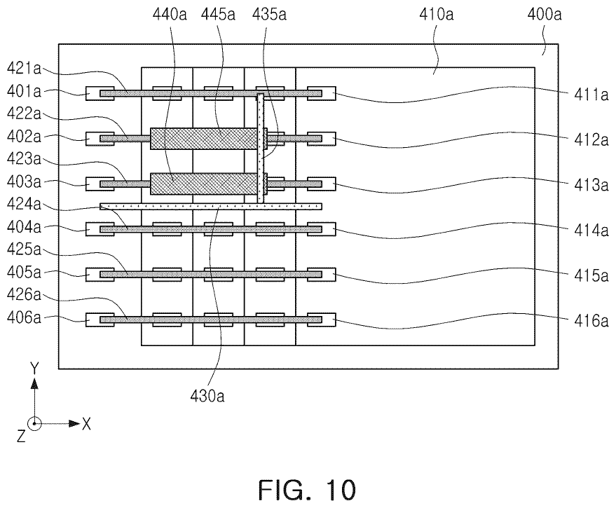

Referring to FIG. 10, at least one dummy line 430a may be disposed between the first signal line 423a and the second signal line 424a. The at least one dummy line 430a may be connected to a power voltage or a ground voltage through at least one dummy connection line 435a.

In an example embodiment, the dummy connection line 435a may have an area overlapping (e.g., above) the first signal line 423a and the second connection line 422a. The first insulating pattern 440a may be disposed between the dummy connection line 435a and the first signal line 423a, and the first insulating pattern 440a may surround the side and upper surface of the first signal line 423a. The second insulating pattern 445a may be disposed between the dummy connection line 435a and the second connection line 422a, and the second insulating pattern 445b may surround the side and upper surface of the second connection line 422a. The first insulating pattern 440a and the second insulating pattern 445a may be physically separated from each other.

The widths of each of the first insulating pattern 440a and the second insulating pattern 445a in the second direction (X-axis direction) may be larger than the width of each of the plurality of pads 411a to 416a. In an example embodiment, the widths of each of the first insulating pattern 440a and the second insulating pattern 445a may be larger than the combined widths of three pads in the second direction (X-axis direction). Since the widths of the first insulating pattern 440a and the second insulating pattern 445a are relatively large, a plurality of dummy connection lines 435a may be disposed above the first insulating pattern 440a and the second insulating pattern 445a in the first direction.

By disposing at least one dummy line 430a connected to the power supply voltage or the ground voltage, the size of the mutual inductance and/or capacitance formed between the two adjacent signal lines 423a and 424a may be reduced, and the crosstalk formed due to this may also be reduced. Accordingly, a semiconductor package with improved signal quality may be provided.

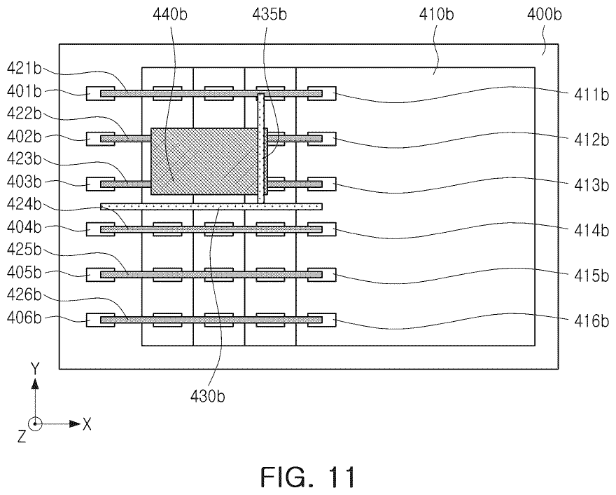

Referring to FIG. 11, at least one dummy line 430b may be disposed between the first signal line 423b and the second signal line 424b. At least one dummy line 430b may be connected to a power supply voltage or a ground voltage through at least one dummy connection line 435b.

In an example embodiment, the dummy connection line 435b may have an area overlapping (e.g., above) the first signal line 423b and the second connection line 422b. In the first direction (Z-axis direction), the insulating pattern 440b may be disposed between the dummy connection line 435b and the first signal line 423b and the second connection line 422b. The insulating pattern 440b may surround the side and upper surfaces of the first signal line 423b and the second connection line 422b. In the first direction, a plurality of dummy connection lines 435b may be disposed above the insulating pattern 440b.

In the second direction (X-axis direction), the width of the insulating pattern 440b may be larger than the width of each of the plurality of pads 411b to 416b. In an example embodiment, the width of the insulating pattern 440b in the second direction (X-axis direction) may be larger than the combined widths of three pads. Since the width of the insulating pattern 440b is relatively large, a plurality of dummy connection lines 435b may be disposed above the insulating pattern 440b in the first direction. In the third direction (Y-axis direction), the width of the insulating pattern 440b may be larger than the width of each of the plurality of pads 411b to 416b, which may reduce the effect of crosstalk caused by two adjacent signal lines and may improve signal quality. For example, the width of the insulating pattern 440b in the third direction may be larger than the combined widths in the third direction of two pads of the plurality of pads 411b to 416b.

By disposing at least one dummy line 430b connected to a power voltage or a ground voltage, the size of the mutual inductance and/or capacitance formed between two adjacent signal lines 423b, 424b may be reduced, and thus the crosstalk formed may also be reduced. Accordingly, a semiconductor package with improved signal quality may be provided.

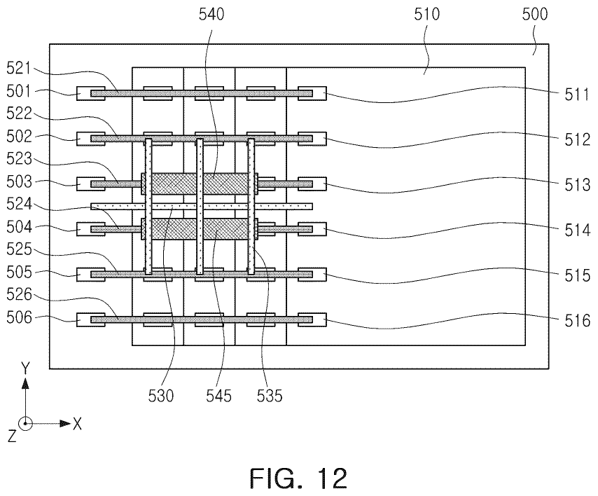

Referring to FIG. 12, a semiconductor package according to an example embodiment may include a package substrate 500, a plurality of semiconductor chips 510, a plurality of connection lines 521 to 526, at least one dummy line 530, and a plurality of dummy connection lines 535.

The package substrate 500 may include a plurality of bonding pads 501 to 506. The plurality of semiconductor chips 510 are mounted on the upper surface of the package substrate 500 and may each include a plurality of pads 511-516, respectively. The plurality of pads 511-516 may include a pair of adjacent pads 513, 514 that transmit or receive a data signal, which is a differential signal.

The plurality of connection lines 521 to 526 may connect the plurality of pads 511-516 of each of the semiconductor chips 510 to each other and to the plurality of bonding pads 501 to 506, respectively. The plurality of connection lines 521 to 526 may include a first connection line 522 and a second connection line 525 that provide a ground voltage. The first connection line 522 may connect a ground voltage pad 512 to a second bonding pad 502 included in the plurality of bonding pads 501 to 506. The second connection line 525 may connect another ground voltage pad 515 to a fifth bonding pad 505 included in the plurality of bonding pads 501 to 506. In addition, the plurality of connection lines 521 to 526 may include a first signal line 523 and a second signal line 524 that are respectively connected to a pair of pads 513, 514.

At least one dummy line 530 may be disposed between a pair of pads 513, 514. The plurality of dummy connection lines 535 may connect the first connection line 522 and the second connection line 525 to at least one dummy line 530. Referring to FIG. 12, in an example embodiment, there are six dummy connection lines 535. Three dummy connection lines 535 may connect the first connection line 522 to the dummy line 530, and the other three dummy connection lines 535 may connect the second connection line 525 to the dummy line 530.

At least one or more insulating patterns 540 and 545 may be disposed in an area where the dummy connection line 535 overlaps (e.g., crosses above) the first signal line 523 and the second signal line 524. In an example embodiment, the first insulating pattern 540 may be disposed in an area where the first signal line 523 and the plurality of dummy connection lines 535 overlap. The second insulating pattern 545 may be disposed in an area where the second signal line 524 and the plurality of dummy connection lines 535 overlap. In an example embodiment, the first insulating pattern 540 and the second insulating pattern 545 may be disposed in multiples.

In an example embodiment, by disposing at least one dummy line 530 connected to a power supply voltage or a ground voltage, the size of the mutual inductance and/or capacitance formed between two adjacent signal lines 523 and 524 may be reduced, and thus the crosstalk formed may also be reduced. Accordingly, a semiconductor package with improved signal quality may be provided.

As set forth above, a semiconductor package according to an example embodiment includes a first signal line and a second signal line disposed adjacent to each other, and at least one dummy line may be disposed between the first signal line and the second signal line. By disposing at least one dummy line between the first signal line and the second signal line, an influence of crosstalk caused by mutual inductance and/or capacitance formed between two signal lines may be reduced, and the quality of a signal may be improved.

While example embodiments have been illustrated and described above, it will be apparent to those skilled in the art that modifications and variations could be made without departing from the scope of the present inventive concept.

What is claimed is:

1. A semiconductor package comprising:
a package substrate including a plurality of bonding pads, the plurality of bonding pads including a first bonding pad and a second bonding pad;
a plurality of semiconductor chips mounted on an upper surface of the package substrate, each of the plurality of semiconductor chips including a respective plurality of pads, wherein for each of the plurality of semiconductor chips, the respective plurality of pads includes a power voltage pad, a ground voltage pad, a first signal pad, and a second signal pad adjacent to the first signal pad;
a plurality of connection lines including a first signal line connecting each of the first signal pads to the first bonding pad, a second signal line connecting each of the second signal pads to the second bonding pad, a first connection line connecting each of the power voltage pads to a respective bonding pad of the plurality of bonding pads, and a second connection line connecting each of the ground voltage pads to a respective bonding pad of the plurality of bonding pads; and
a first dummy line disposed between the first signal line and the second signal line.

2. The semiconductor package of claim 1, wherein the plurality of semiconductor chips are stacked in a stepwise manner in a first direction perpendicular to the upper surface of the package substrate.

3. The semiconductor package of claim 1, further comprising a second dummy line connecting the first dummy line to a ground voltage.

4. The semiconductor package of claim 3, wherein a portion of the second dummy line overlaps with a first pad among the plurality of pads of one of the plurality of semiconductor chips in a first direction perpendicular to the upper surface of the package substrate.

5. The semiconductor package of claim 4, further comprising an insulating pattern disposed between a first connection line among the plurality of connection lines and the second dummy line, in the first direction.

6. The semiconductor package of claim 5, wherein the insulating pattern overlaps with a second pad of the plurality of pads of one of the plurality of semiconductor chips.

7. The semiconductor package of claim 1, further comprising a second dummy line connecting the second connection line to the first dummy line,
wherein the second connection line is disposed adjacent to the first signal line.

8. The semiconductor package of claim 7, further comprising a first insulating pattern disposed between the first signal line and the second dummy line in a first direction perpendicular to the upper surface of the package substrate,
wherein the first insulating pattern surrounds a side surface and an upper surface of the first signal line.

9. The semiconductor package of claim 8, wherein a width of the first insulating pattern is greater than a width of each of the plurality of pads, in a second direction parallel to the upper surface of the package substrate.

10. The semiconductor package of claim 1, further comprising a second dummy line connecting the second connection line to the first dummy line,
wherein one of the plurality of connection lines is disposed between the second connection line and the first signal line.

11. The semiconductor package of claim 10, further comprising:
a first insulating pattern disposed between the first signal line and the second dummy line, the first insulating pattern surrounding a side surface and an upper surface of the first signal line, in a first direction perpendicular to the upper surface of the package substrate; and
a second insulating pattern disposed between the one of the plurality of connection lines and the second dummy line and surrounding a side surface and an upper surface of the one of the plurality of connection lines, in the first direction.

12. The semiconductor package of claim 10, wherein the semiconductor package includes an insulating pattern disposed between the first signal line, the second connection line, and the second dummy line, the insulating pattern surrounding respective side and upper surfaces of the first signal line and the one of the plurality of connection lines.

13. The semiconductor package of claim 12, wherein a width of the insulating pattern is larger than a combined width of two pads of the plurality of pads of a semiconductor chip of the plurality of semiconductor chips in a third direction parallel to the upper surface of the package substrate.

14. The semiconductor package of claim 1, further comprising a second dummy line connecting the second connection line, a third connection line included in the plurality of connection lines, and the first dummy line to each other,
wherein the second connection line and the third connection line are configured to provide a ground voltage to the first dummy line through the second dummy line.

15. The semiconductor package of claim 14, wherein the first connection line is adjacent to the first signal line, and the second connection line is adjacent to the second signal line.

16. The semiconductor package of claim 1, wherein for each of the plurality of semiconductor chips, the respective plurality of pads are disposed on upper surface edges of the plurality of semiconductor chips.

17. The semiconductor package of claim 1, wherein the plurality of semiconductor chips are identical semiconductor chips.

18. The semiconductor package of claim 1, wherein the plurality of connection lines and the first dummy line include a conductive ink.

19. A semiconductor package comprising:
a package substrate including a plurality of bonding pads;
a plurality of semiconductor chips mounted on an upper surface of the package substrate, each of the plurality of semiconductor chips including a first signal pad and a second signal pad;
a plurality of connection lines including a first signal line connecting the first signal pad of each of the plurality of semiconductor chips to a first bonding pad of the plurality of bonding pads, and a second signal line connecting the second signal pad of each of the plurality of semiconductor chips to a second bonding pad of the plurality of bonding pads, wherein from a top down view, each of the plurality of connection lines extends in a first direction parallel to the upper surface of the package substrate, and wherein the first signal pad and the second signal pad are disposed adjacent to each other in a second direction parallel to the upper surface of the package substrate; and
a first line extending in the first direction positioned between the first signal line and the second signal line, wherein from a top down view, the first line does not directly connect to and does not extend over any chip pads of the plurality of semiconductor chips.

20. A semiconductor package comprising:
a package substrate including a plurality of bonding pads;
a plurality of semiconductor chips mounted on an upper surface of the package substrate, each of the plurality of semiconductor chips including a respective plurality of pads, wherein for each of the plurality of semiconductor chips, the respective plurality of pads includes a pair of pads adjacent to each other that are configured to transmit or receive a data signal;
a plurality of connection lines connecting the plurality of pads of each of the plurality of semiconductor chips to respective bonding pads of the plurality of bonding pads, the plurality of connection lines including a first connection line configured to provide a ground voltage, a second connection line configured to provide the ground voltage, and a first signal line and a second signal line respectively connected to the pair of pads of each of the plurality of semiconductor chips;
a first dummy line between the pair of pads of each of the plurality of semiconductor chips;
a plurality of second dummy lines connecting the first connection line and the second connection line to the first dummy line; and
a first insulating pattern disposed between the first signal line, the second signal line, and the plurality of second dummy lines.
